(19) United States
(12) Patent Application Publication
(10) Pub. No.: US 2019/0229154 A1
(43) Pub. Date: Jul. 25, 2019

(54) TOUCH OLED DISPLAY PANEL AND DISPLAY DEVICE

(71) Applicant: Wuhan China Star Optoelectronics Technology Co., Ltd., Wuhan, Hubei (CN)

(72) Inventor: Yuejun TANG, Wuhan, Hubei (CN)

(21) Appl. No.: 15/578,688

(22) PCT Filed: Nov. 15, 2017
(86) PCT No.: PCT/CN2017/111059

§ 371 Date: Nov. 30, 2017

(30) Foreign Application Priority Data
Nov. 1, 2017 (CN) 201711057699.5

(51) Int. Cl. H01L 27/32; G06F 3/041; H01L 51/00; H01L 51/52

(52) U.S. Cl. CPC H01L 27/323; H01L 51/5203; H01L 51/0097; G06F 3/0412

(57) ABSTRACT

The present disclosure discloses a touch OLED display panel including a flexible array substrate, a package cover and a display area; wherein a chip bonding portion and a first connection terminal are electrically connected to each other, a touch electrode and a second connection terminal are electrically connected to each other on a side of the package cover, the chip bonding portion and the first connection terminal are respectively located at two different sides outside the display area, and the first connection terminal and the second connection terminal are located at a same side outside the display area. A side of the flexible array substrate arranged with the first connection terminal is bent and connected to the package cover, and the second connection terminal and the first connection terminal are electrically connected to each other. The present disclosure further discloses a display device including the touch OLED display panel.

### RELATED APPLICATIONS

The present application is a National Phase of International Application Number PCT/CN2017/111059, filed Nov. 15, 2017, and claims the priority of China Application No. 201711057699.5, filed Nov. 1, 2017.

### FIELD OF THE DISCLOSURE

The present disclosure relates to a display technology field, and more particularly to a touch OLED display panel and a display device.

### BACKGROUND OF THE DISCLOSURE

With the development of the information age and the accelerating pace of life, touch technology has gradually replaced the traditional mouse and keyboard because of its user-friendly design and simple and quick input. It has been widely applied to a wide range of electronic products. Wherein the capacitive touch screen due to its advantages of fast response, high sensitivity, high reliability and durability are widely used.

OLED (Organic Light Emitting Diode) display device has self-luminous, wide viewing angle, high luminous efficiency, low power consumption, fast response time, low temperature characteristics, simply manufacturing process, low cost and other characteristics. At present, the touch OLED display device generally adopts separating the OLED display panel and the touch screen to form, and then combines the two together (i.e. the add on mode). This touch OLED display device has the disadvantages of low light transmittance and thick.

### SUMMARY OF THE DISCLOSURE

In view of the deficiencies of the prior art, the present disclosure provides a touch OLED display panel. The touch structure is embedded in the OLED display panel and has the advantages of simple structure, thin thickness and high light transmittance.

In order to achieve the above object, the present disclosure adopts the following technical solutions:

A touch OLED display panel, including a flexible array substrate and a package cover opposite to each other, and a display area; wherein a chip bonding portion and a first connection terminal are electrically connected to each other on the flexible array substrate, a touch electrode and a second connection terminal are electrically connected to each other on a side of the package cover away from the flexible array substrate, the chip bonding portion and the first connection terminal are respectively located at two different sides outside the display area, and the first connection terminal and the second connection terminal are located at a same side outside the display area; wherein, a side of the flexible array substrate arranged with the first connection terminal is bent and connected to the package cover, and the second connection terminal and the first connection terminal are electrically connected to each other.

Wherein the chip bonding portion is arranged on a first side outside the display area, and the first connection terminal and the second connection terminal are arranged on a second side opposite to the first side outside the display area.

Wherein the chip bonding portion is arranged on a first side outside the display area, the first connection terminal and the second connection terminal are arranged on a third side and a fourth side adjacent the first side outside the display area.

Wherein the third side and the fourth side outside the display area are arranged with the first connection terminal on the flexible array substrate; correspondingly, the third side and the fourth side outside the display area are arranged with the second connection terminal on the package cover.

Wherein a connection trace between the first connection terminal and the chip bonding portion is arranged at an edge area of the flexible array substrate.

Wherein an organic light emitting structure layer is arranged on the flexible array substrate, and a sealant is arranged between the flexible array substrate and the package cover; wherein the sealant is arranged around the organic light emitting structure layer, and the chip bonding portion and the first connection terminal are all outside the sealant.

Wherein the touch electrode layer includes a plurality of square electrodes arranged in an array, the plurality of square electrodes is insulated from each other in the same structural layer, and each of the square electrodes is connected to the second connection terminal through a corresponding touch connection line.

Wherein the touch electrode layer includes a driving electrode and a sensing electrode, the driving electrode and the sensing electrode are insulated from each other and arranged in different structural layers, and each of the driving electrode and the sensing electrode is connected to the second connection terminal through a corresponding touch connection line.

Wherein the organic light emitting structure layer includes an anode layer, a luminescent material layer and a cathode layer arranged on the flexible array substrate sequentially.

The present disclosure further provides a display device, the display device includes a driving unit and the touch OLED display panel as described above, the driving unit provides a driving signal to the touch OLED display panel.

According to the touch type OLED display panel and the display device provided in the embodiments of the present disclosure, the touch structure is arranged in the OLED display panel. Specifically, the touch structure is arranged on a side of the package cover far away from the flexible array substrate to form an on-cell touch structure, which has the advantages of simple structure, thin thickness and high light transmittance. In addition, in the non-display area of the display panel, the flexible array substrate is bent and connected to the package cover, so that the two are electrically connected. Thereby, the same chip bonding portion can be shared by a display driver and a touch driver, which not only reduces the difficulty of the bonding process but also reduces the cost.

### BRIEF DESCRIPTION OF THE DRAWINGS

FIG. 1 is a schematic plan view of a touch OLED display panel according to Embodiment 1 of the present disclosure;

FIG. 2 is a cross-sectional view taken along line Y1-Y1 in FIG. 1;

FIG. 3 is a schematic structural view of a touch electrode layer in an embodiment of the present disclosure;

FIG. 4 is a schematic structural view of a touch electrode layer according to another specific embodiment of the present disclosure;

FIG. 5 is a schematic plan view of a touch OLED display panel according to Embodiment 2 of the present disclosure;

FIG. 6 is a cross-sectional view taken along line Y2-Y2 in FIG. 5;

FIG. 7 is a cross-sectional view taken along line X1-X1 in FIG. 5;

FIG. 8 is a schematic plan view of a touch OLED display panel according to Embodiment 3 of the present disclosure;

FIG. 9 is a cross-sectional view taken along line X2-X2 in FIG. 8,

FIG. 10 is a schematic structural diagram of a display device provided in Embodiment 4 of the present disclosure.

### DETAILED DESCRIPTION OF PREFERRED EMBODIMENTS

To make the objectives, technical solutions, and advantages of the present disclosure clearer, the following describes the specific implementation manners of the present disclosure in detail with reference to the accompanying drawings. Examples of these preferred embodiments are illustrated in the drawings. The embodiments of the present disclosure shown in the drawings and described in the drawings are merely exemplary and the present disclosure is not limited to these embodiments.

Here, it should also be noted that, in order to avoid obscuring the present disclosure with unnecessary detail, only the structures and/or processing steps that are closely related to the solution according to the present disclosure are shown in the drawings, and other details that are of less concern to the present disclosure are omitted.

### Embodiment 1

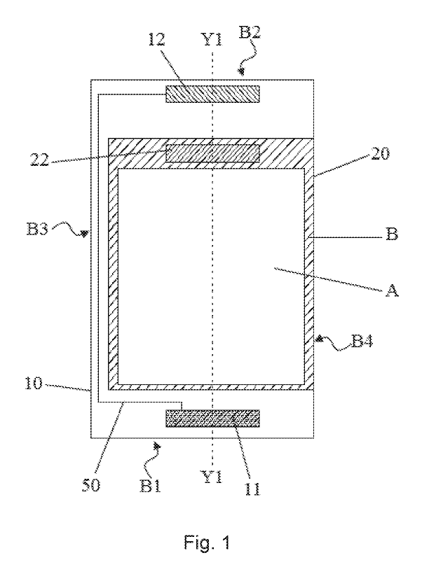

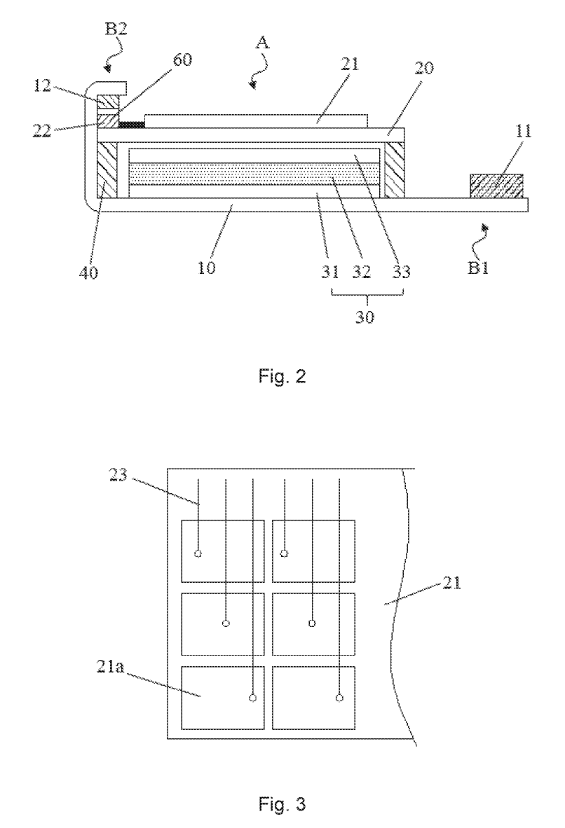

The present embodiment provides a touch OLED display panel, refer to FIG. 1 and FIG. 2, the touch OLED display panel includes a flexible array substrate 10 and a package cover 20 opposite to each other, an organic light emitting structure layer 30 and a sealant 40 arranged between the flexible array substrate 10 and the package cover 20. Wherein the sealant 40 is arranged around the organic light emitting structure layer 30, the flexible array substrate 10, the package cover 20 and the sealant 40 together form a sealed chamber, the organic light emitting structure layer 30 is arranged in the sealed chamber. The organic light emitting structure layer 30 includes an anode layer 31, a luminescent material layer 32 and a cathode layer 33 arranged on the flexible array substrate 10 sequentially.

Wherein the base substrate of the flexible array substrate 10 is a flexible substrate, for example, a flexible substrate formed of a polymer material such as Polyimide (PI), Polycarbonate (PC), Polyethersulfone (PES), Polyethylene Terephthalate (PET), Polyethylene Naphthalate (PEN), Polyarylate (PAR) or glass fiber reinforced plastic (FRP). A display driving circuit (not shown) is arranged in the flexible array substrate 10, the display driving circuit mainly includes thin film transistors and signal traces such as data lines and scan lines arranged in an array.

Wherein the touch OLED display panel includes a display area A and a non-display area B, the non-display area B surrounds the display area A including the first side B1, the second side B2, the third side B3 and the fourth side B4 outside the display area A. Wherein the first side B1 and the second side B2 are two opposite sides, and the third side B3 and the fourth side B4 are two opposite sides.

Wherein the flexible array substrate 10 is provided with a chip bonding portion 111 and a first connection terminal 12 electrically connected to each other, a side of the package cover 20 away from the flexible array substrate 10 is provided with a touch electrode layer 21 and a second connection terminal 22 electrically connected to each other. Specifically, the chip bonding portion 11 and the first connection terminal 12 are in the non-display area B of the flexible array substrate 10 and outside the sealant 40, the chip bonding portion 11 and the first connection terminal 12 are electrically connected to each other through a connection trace 50; the touch electrode layer 21 is in the display area A of the package cover 20, the second connection terminal 22 is in the non-display area B of the package cover 20.

Further, the chip bonding portion 11 and the first connection terminal 12 are respectively located at two different sides outside the display area A, the second connection terminal 22 and the first connection terminal 12 are located at a same side outside the display area A. In the present embodiment, as shown in FIG. 1, the chip bonding layer is located at the first side B1 outside the display area A, and the first connection terminal 12 and the second connection terminal 22 are located at the second side B2 opposite to the first side B1 outside the display area A.

Further, the side (second side B2) of the flexible array substrate 10 arranged with the first connection terminal 12 is bent and connected to the package cover 20, the second connection terminal 22 and the first connection terminal 12 are electrically connected to each other. Specifically, an anisotropic conductive adhesive 60 may be arranged between the second connection terminal 22 and the first connection terminal 12 to connect with each other. Thus, the touch electrode layer 21 on the package cover 20 is electrically connected to the chip bonding portion 11 arranged on the flexible array substrate 10 through connected to the second connection terminal 22 and the first connection terminal 12 sequentially. It should be noted that FIG. 1 is a schematic structural diagram of the flexible array substrate 10 when the flexible array substrate 10 is not bent and connected to the package cover 20. FIG. 2 is a cross-sectional view corresponding to the line Y1-Y1 in FIG. 1, and is a schematic structural diagram of the flexible array substrate 10 after bent and connected to the package cover 20.

Wherein the connection trace 50 between the first connection terminal 12 and the chip bonding portion 11 is arranged in an edge area (in the non-display area B) of the flexible array substrate 10. In the present embodiment, as shown in FIG. 1, the connection trace 50 in the non-display area B extends from the first side B1 to the second side B2 through the third side B3, and connects the first connection terminal 12 and the chip bonding portion 11 to each other. In another embodiment, the connection trace 50 may be extends from the first side B1 to the second side B2 through the fourth side B4. It may also be such that a part of the connection trace 50 extends from the first side B1 to the second side B2 through the third side B3, and another part of the connection trace 50 extends from the first side B1 to the second side B2 through the fourth side B4.

Wherein the touch electrode layer 21 includes a touch electrode and a touch driving trace. the touch electrode is electrically connected to the second connection terminal 22 through the touch driving trace. further, for the touch mode and the category, the touch electrode layer may be a touch electrode structure adopting self-capacitance or a touch electrode structure adopting mutual capacitance. In addition, in the arrangement of the structure layer, the touch electrode layer may be a single-layer touch electrode structure or a multi-layer touch electrode structure, the corresponding electrodes and their driving traces therein may be electrically connected to the chip bonding portion 11 through the connection provided by the above embodiment.

Specifically, in the present embodiment, as shown in FIG. 3, the touch electrode layer 21 includes a plurality of square electrodes 21a arranged in an array, the plurality of square electrodes 21a is insulated from each other in the same structural layer, and each of the square electrodes 21a is connected to the second connection terminal 22 through a corresponding touch connection line 23. The electrical connection lines between the respective square electrodes 21a and the chip bonding portions 11 are independent of each other. Only a few of the square electrodes 21a are shown in FIG. 3, and the touch connection line 23 is usually arranged in a different structural layer from the square electrode 21a.

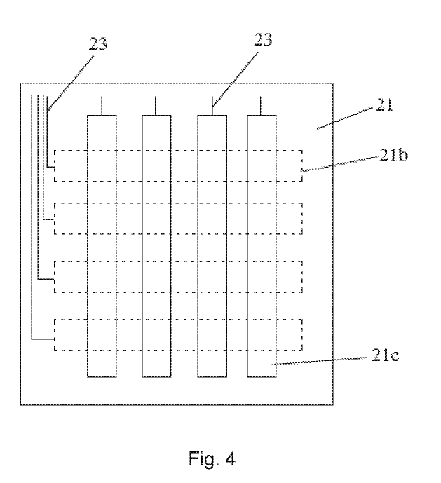

In another specific embodiment, as shown in FIG. 4, the touch electrode layer 21 includes a driving electrode 21b and a sensing electrode 21c, the driving electrode 21b and the sensing electrode 21c are insulated from each other and arranged in different structural layers, and each of the driving electrode 21b and the sensing electrode 21c is connected to the second connection terminal 22 through a corresponding touch connection line 23. Only a few of the driving electrodes 21b and the sensing electrodes 21c are shown in FIG. 4, and the dashed line and the solid line respectively indicate that the driving electrode 21b and the sensing electrode 21c are located in different structural layers.

In the touch OLED display panel and the display device provided in the above embodiments, the touch structure is arranged in the OLED display panel. Specifically, the touch structure is arranged on the side of the package cover away from the flexible array substrate to form an on-cell touch structure, which has the advantages of simple structure, thin thickness and high light transmittance. In addition, in the non-display area of the display panel, the flexible array substrate is bent and connected to the package cover, so that the two are electrically connected. Thereby, the same chip bonding part can be shared by the display driver and the touch driver, which not only reduces the difficulty of the bonding process but also reduces the cost.

### Embodiment 2

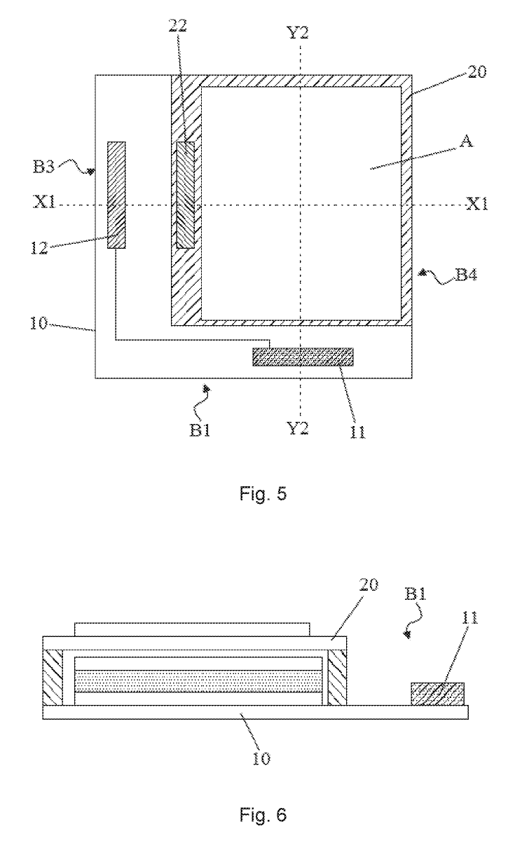

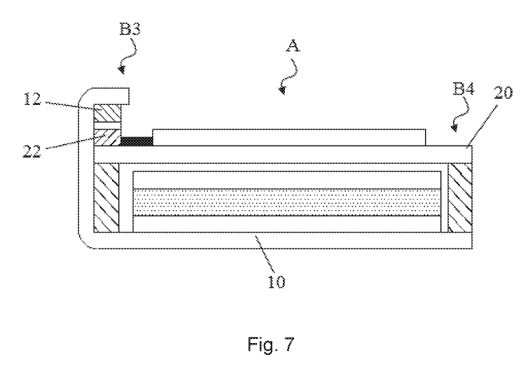

The present embodiment provides a touch OLED display panel, different from Embodiment 1, referring to FIG. 5 to FIG. 7, on the flexible array substrate 10, the chip bonding portion 11 is arranged on a first side B1 outside the display area A, the first connection terminal 12 is arranged on the third side B3 adjacent the first side B1 outside the display area A. on the package cover 20, the second connection terminal 22 is arranged on the third side B3 adjacent the first side B1 outside the display area A, and opposite to the position of the first connection terminal 12. It is easy to understand that the first connection terminal 12 and the second connection terminal 22 may also be arranged on the other side adjacent the first side B1, that is the fourth side B4.

Wherein the side (third side B3) of the flexible array substrate 10 arranged with the first connection terminal 12 is bent and connected on the package cover 20, the second connection terminal 22 and the first connection terminal 12 are electrically connected to each other. Thereby, the touch electrode layer 21 located on the package cover 20 is electrically connected to the chip bonding portion 11 on the flexible array substrate 10 through the second connection terminal 22 and the first connection terminal 12 sequentially. It should be noted that: FIG. 5 is a schematic structural diagram of the flexible array substrate 10 when the flexible array substrate 10 is not bent and connected to the package cover 20. FIG. 6 is a cross-sectional view taken along line Y2-Y2 in FIG. 5, and is a schematic structural diagram of the flexible array substrate 10 bent and connected to the package cover 20. FIG. 7 is a cross-sectional view taken along line X1-X1 in FIG. 5, and is a schematic structural diagram of the flexible array substrate 10 bent and connected to the package cover 20.

In addition, except for the above, the rest of the structure of the touch OLED display panel provided in this embodiment is the same as that in Embodiment 1, and the details are not described herein again.

The touch OLED display panel provided in this embodiment also flexibly connects the flexible array substrate to the package cover to achieve the electrical connection between the two. Thereby, the same chip bonding portion can be shared by the display driver and the touch driver, which not only reduces the difficulty of the bonding process but also reduces the cost.

### Embodiment 3

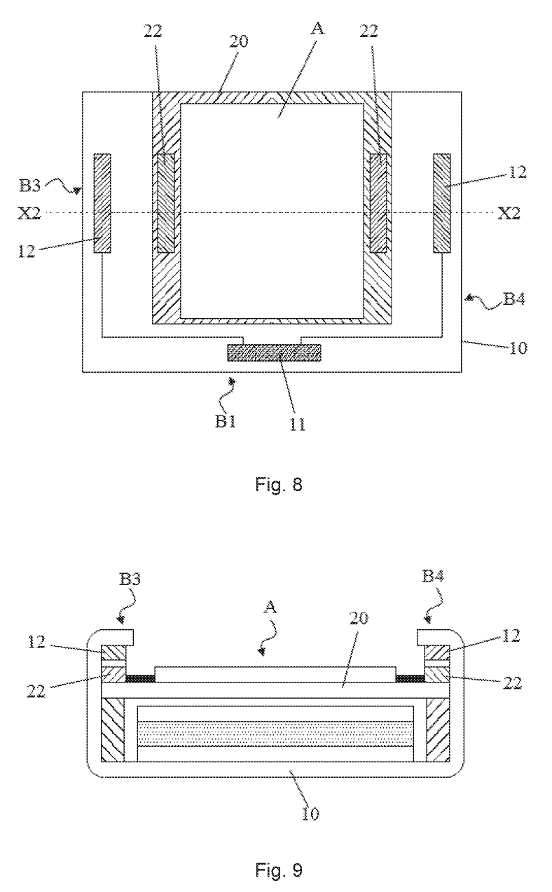

The present embodiment provides a touch OLED display panel. Different from Embodiment 1 and Embodiment 2, referring to FIG. 8 and FIG. 9, on the flexible array substrate 10, the chip bonding portion 11 is arranged on the first side B1 outside the display area A, and the first connection terminal 12 is arranged on the third side B3 and the fourth side B4 outside the display area A. Correspondingly, on the package cover 20, the third side B3 and the fourth side B4 outside the display area A are also provided with the second connection terminal 22.

Wherein the side (third side B3 and fourth side B4) of the flexible array substrate 10 arranged with the first connection terminal 12 is bent and connected on the package cover 20, the second connection terminal 22 and the first connection terminal are electrically connected to each other, specifically, the first connection terminal 12 on the third side B3 is connected to the second connection terminal 22 on the third side B3, the first connection terminal 12 on the fourth side B4 is connected to the second connection terminal 22 on the fourth side B4. Wherein part of the electrodes in the touch electrode layer 21 are connected to the second connection terminal 22 on the third side B3 through the corresponding touch connection line, the other part of the electrodes in the touch electrode layer 21 are connected to the second connection terminal 22 on the fourth side B4 through the corresponding touch connection line. Thereby, the touch electrode layer 21 on the package cover 20 is electrically connected to the chip bonding portion 11 on the flexible array substrate 10 through the second connection terminal 22 and the first connection terminal 12 sequentially.

Is should be noted that: FIG. 8 is a schematic structural diagram of the flexible array substrate 10 when the flexible array substrate is not bent and connected to the package cover 20. FIG. 9 is a cross-sectional view taken along line X2-X2 in FIG. 8, and is a schematic structural diagram of the flexible array substrate 10 bent and connected to the package cover 20. In addition, except for the above, the rest of the structure of the touch OLED display panel provided in this embodiment is the same as that in Embodiment 1, and the details are not described herein again.

The touch OLED display panel provided in this embodiment also flexibly connects the flexible array substrate to the package cover to achieve the electrical connection between the two. Thereby, the same chip bonding portion can be shared by the display driver and the touch driver, which not only reduces the difficulty of the bonding process but also reduces the cost.

### Embodiment 4

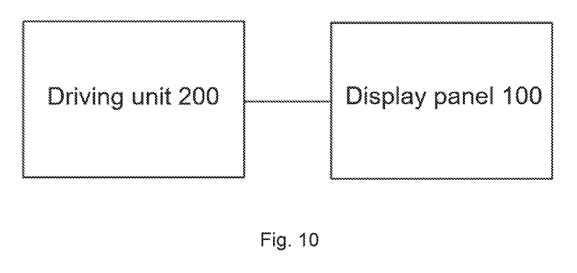

The present embodiment provides a display device, as shown in FIG. 10, the display device includes a driving unit and an OLED display panel 100, the driving unit 200 provides a driving signal to the OLED display panel 100. The OLED display panel 100 employs the touch OLED display panel described in Embodiment 1 or Embodiment 2 of the present disclosure. Wherein the driving signal includes a display driving signal and a touch driving signal, specifically, the driving unit 200 includes a display driver chip and a touch driver chip, the display driver chip and the touch driver chip are connected to the chip bonding portion on the flexible array substrate respectively. In some specifically embodiment, the display driver chip and the touch driver chip can be integrated in the same chip with the display driving function and the touch driving function.

In summary, the touch OLED display panel and the display device provided by the embodiment of the present disclosure, the touch structure is arranged in the OLED display panel, specifically, the touch structure is arranged on the side of the package cover away from the flexible array substrate to form an On-cell touch structure, which has the advantages of simple structure, thin thickness and high light transmittance. In addition, the flexible array substrate is bent and connected to the package cover, so that the two are electrically connected. Thereby, the same chip bonding portion can be shared by the display driver and the touch driver, which not only reduces the difficulty of the bonding process but also reduces the cost.

It should be noted that, in this article, relational terms, such as first and second, and the like, are only used to distinguish one entity or operation from another, not necessarily requiring or implying any actual relationship or order between such entities or operations. Moreover, the terms “comprising,” “including,” or any other variation thereof, are intended to cover a non-exclusive inclusion such that a process, method, article, or apparatus that includes a list of elements includes not only those elements, but also include other elements not expressly listed or also include elements inherent to the process, method, article, or device. Without further limitations, an element limited by the statement “including a . . . ” does not exclude the existence of additional identical elements in the process, method, article, or apparatus that includes the element.

The foregoing descriptions are merely specific implementation manners of the present application. It should be noted that, for those skilled in the art, several improvements and modifications can be made without departing from the principle of the present disclosure, and these improvements and modifications should also be considered as the protection scope of the present application.

What is claimed is:

1. A touch OLED display panel, comprising a flexible array substrate and a package cover opposite to each other, and a display area; wherein,
a chip bonding portion and a first connection terminal are electrically connected to each other on the flexible array substrate, a touch electrode and a second connection terminal are electrically connected to each other on a side of the package cover away from the flexible array substrate, the chip bonding portion and the first connection terminal are respectively located at two different sides outside the display area, and the first connection terminal and the second connection terminal are located at a same side outside the display area;
wherein, a side of the flexible array substrate arranged with the first connection terminal is bent and connected to the package cover, and the second connection terminal and the first connection terminal are electrically connected to each other.

2. The touch OLED display panel according to claim 1, wherein the chip bonding portion is arranged on a first side outside the display area, and the first connection terminal and the second connection terminal are arranged on a second side opposite to the first side outside the display area.

3. The touch OLED display panel according to claim 1, wherein the chip bonding portion is arranged on a first side outside the display area, the first connection terminal and the second connection terminal are arranged on a third side and a fourth side adjacent the first side outside the display area.

4. The touch OLED display panel according to claim 3, wherein the third side and the fourth side outside the display area are arranged with the first connection terminal on the flexible array substrate; correspondingly, the third side and the fourth side outside the display area are arranged with the second connection terminal on the package cover.

5. The touch OLED display panel according to claim 1, wherein a connection trace between the first connection terminal and the chip bonding portion is arranged at an edge area of the flexible array substrate.

6. The touch OLED display panel according to claim 1, wherein an organic light emitting structure layer is arranged on the flexible array substrate, and a sealant is arranged between the flexible array substrate and the package cover; wherein the sealant is arranged around the organic light emitting structure layer, and the chip bonding portion and the first connection terminal are all outside the sealant.

7. The touch OLED display panel according to claim 6, wherein the touch electrode layer comprises a plurality of square electrodes arranged in an array, the plurality of square electrodes is insulated from each other in the same structural layer, and each of the square electrodes is connected to the second connection terminal through a corresponding touch connection line.

8. The touch OLED display panel according to claim 6, wherein the touch electrode layer comprises a driving electrode and a sensing electrode, the driving electrode and the sensing electrode are insulated from each other and arranged in different structural layers, and each of the driving electrode and the sensing electrode is connected to the second connection terminal through a corresponding touch connection line.

9. The touch OLED display panel according to claim 6, wherein the organic light emitting structure layer comprises an anode layer, a luminescent material layer and a cathode layer arranged on the flexible array substrate sequentially.

10. The touch OLED display panel according to claim 1, wherein the second connection terminal and the first connection terminal are electrically connected to each other by an anisotropic conductive adhesive.

11. A display device, comprising a driving unit and a touch OLED display panel, wherein the driving unit provides a driving signal to the touch OLED display panel, and the touch OLED display panel comprises a flexible array substrate and a package cover opposite to each other, and a display area; wherein,
a chip bonding portion and a first connection terminal are electrically connected to each other on the flexible array substrate, a touch electrode and a second connection terminal are electrically connected to each other on a side of the package cover away from the flexible array substrate, the chip bonding portion and the first connection terminal are respectively located at two different sides outside the display area, and the first connection terminal and the second connection terminal are located at a same side outside the display area;
wherein, a side of the flexible array substrate arranged with the first connection terminal is bent and connected to the package cover, and the second connection terminal and the first connection terminal are electrically connected to each other.

12. The display device according to claim 11, wherein the chip bonding portion is arranged on a first side outside the display area, and the first connection terminal and the second connection terminal are arranged on a second side opposite to the first side outside the display area.

13. The display device according to claim 11, wherein the chip bonding portion is arranged on a first side outside the display area, the first connection terminal and the second connection terminal are arranged on a third side and a fourth side adjacent the first side outside the display area.

14. The display device according to claim 13, wherein the third side and the fourth side outside the display area are arranged with the first connection terminal on the flexible array substrate; correspondingly, the third side and the fourth side outside the display area are arranged with the second connection terminal on the package cover.

15. The display device according to claim 11, wherein a connection trace between the first connection terminal and the chip bonding portion is arranged at an edge area of the flexible array substrate.

16. The display device according to claim 11, wherein an organic light emitting structure layer is arranged on the flexible array substrate, and a sealant is arranged between the flexible array substrate and the package cover; wherein the sealant is arranged around the organic light emitting structure layer, and the chip bonding portion and the first connection terminal are all outside the sealant.

17. The display device according to claim 16, wherein the touch electrode layer comprises a plurality of square electrodes arranged in an array, the plurality of square electrodes is insulated from each other in the same structural layer, and each of the square electrodes is connected to the second connection terminal through a corresponding touch connection line.

18. The display device according to claim 16, wherein the touch electrode layer comprises a driving electrode and a sensing electrode, the driving electrode and the sensing electrode are insulated from each other and arranged in different structural layers, and each of the driving electrode and the sensing electrode is connected to the second connection terminal through a corresponding touch connection line.

19. The display device according to claim 16, wherein the organic light emitting structure layer comprises an anode layer, a luminescent material layer and a cathode layer arranged on the flexible array substrate sequentially.

20. The display device according to claim 11, wherein the second connection terminal and the first connection terminal are electrically connected to each other by an anisotropic conductive adhesive.
